(19) United States
(12) Patent Application Publication
(10) Pub. No.: US 2015/0234011 A1
(43) Pub. Date: Aug. 20, 2015

(54) REAL TIME MONITORING OF ROTOR OR STATOR SHAPE CHANGE FOR ROTATING MACHINES

(71) Applicant: VIBROSYSTM INC., Longueuil (CA)

(72) Inventor: Marius CLOUTIER, Longueuil (CA)

(21) Appl. No.: 14/624,867

(22) Filed: Feb. 18, 2015

Related U.S. Application Data
(60) Provisional application No. 61/941,548, filed on Feb. 19, 2014.

(51) Int. Cl. G01R 31/34

(52) U.S. Cl. CPC G01R 31/343

(57) ABSTRACT

A monitoring system for rotor or stator shape changes detection of a rotating machine which can be used with an electric rotating machine with salient pole rotor. The system comprising: at least one gap measuring sensor affixed on the stator and producing real time measurements of gap thickness for each passing rotor reference point and associating the real time measurements to a unique identifier for each rotor reference point; a memory for storing reference values of gap thickness for each rotor reference point and each sensor position; a comparator for comparing corresponding ones of the real time measurements and the references values and identifying a positive or negative variation in the gap thickness greater than a predetermined minimum percentage; and a warning signal generator for emitting at least one warning signal.

### TECHNICAL FIELD

The invention relates to large rotating machines and more particularly to a real time monitoring of rotor or stator shape changes.

### BACKGROUND OF THE ART

In large rotating electric machines such as hydroelectric generators, rotor diameters often range from 5 to 15 m. Generally, the distance or air gap, varies from 5 to 30 mm with an initial tolerance of ±15%. However, as time goes by, measured air gap thicknesses often vary by more than 25%. Standards used in the industry allow for up to 30% variations, a constraint that still remains quite challenging when such large diameters are taken into account.

Several factors can cause air gap thicknesses to vary that may be caused either by the relative eccentricity of the rotation of the rotor inside the stator or by a change in the circumferential profile (hereafter “shape”) of the rotor or of the stator.

With time and depending on the operation of the machine, defects in design, fabrication or maintenance can emerge, due to the intense electromagnetic forces existing in the stator and rotor, combined with the important centrifugal forces acting on the rotor, and with the thermal and mechanical constraints acting on the rotating and fixed parts.

A common practice in the industry is to monitor the air gap thickness by using 4 or 8 proximity sensors affixed periodically around the stator wall at 90° or 45° intervals and facing the rotor so that each sensor measures the air gap thickness for each passing rotor pole. Each pole on the rotor is identified and tracked using a “synchro probe” or “key phaser” that provides one pulse per turn for a reference point chosen on the rotating part.

Since poles may not be absolutely identical and mounted or fabricated in the exact same way, the distances measured vary and may differ by up to 25% from one pole to the other.

Air gap measurements can thus be performed for each pole for each sensor. For instance, for 8 air gap sensors and a 60 pole rotor, a 8×60=480 points matrix is generated during one turn, giving 480 values of air gap thicknesses.

From such values, one can derive the relative shapes of the rotor and stator as “seen” from the sensors. For example, for each sensor, the air gap profile represented by the minimum air gap values for each passing pole corresponds to the shape of the rotor that can be represented in x,y as well as in polar coordinates. To approximate the shape of the stator, one may calculate the averages of the minimum distances obtained by each sensor for all poles and operate a curve-fitting algorithm (for instance a spline interpolation) between these minimum average distances in polar coordinates.

An example of such a prior art graphical representation 100 of the motor is seen in FIG. 1. The reference shape for the rotor 106 and the reference shape for the stator 104 are shown in dotted lines. The rotor profile 108 and the stator profile 102 are obtained using four sensors 110 equally spaced at 45°, 135°, 225° and 315°. The rotor profile 108 is acquired by the sensor provided at 45° in this example representation. The sensors 110 measure the air gap thickness facing each of 64 rotor poles.

FIG. 2 shows a graph 200 of the air gap thickness (vertical scale) as measured by each of the four sensors 202, 204, 206, 208 for each passing pole (horizontal scale) over one machine turn in Cartesian coordinates for an example prior art measurement set. All profiles have a similar shape which indicates a normal configuration for the stator and the rotor. However, as can be seen, the pole thickness variation is greater than 0.10 mm (˜0.29 mm), namely greater than 10% of the air gap.

To protect a hydro-generator against dangerous or catastrophic events resulting from excessive diminution or even disappearance of the air gap, alarm levels are programmed for all rotor poles passing in front of a sensor, and for each sensor.

For instance, example mechanical tolerances 300 are shown in the table of FIG. 3. The tolerances 300 include proposed deviations 312 for alarm levels including erection 314, acceptable 316 and critical 318 for the air gap 302, the stator roundness 304, the stator concentricity 306, the rotor roundness 308 and the rotor concentricity 310. Note that the deviation 312 is expressed in percentage of the theoretical (nominal) values.

Programming these alarm levels has the following limitations.

An air gap alarm based on the air gap deviations shown in FIG. 3 does not guarantee the integrity of the rotor or of the stator. It is possible that an abnormal deformation of the stator or of the rotor can be occurring even though the global air gap thickness remains inside the acceptable values at all times. FIG. 4 shows an actual case of rotor shape change due to a loose rim section detected by comparison during a time period of 9 days. Graph 400 shows the air gap thickness (vertical scale) as measured by each of the four sensors 402, 404, 406 and 408 for each position for another example prior art measurement set. In that case, curve 404 ceases to parallel the other curves and intersects curves 402 and 406. The anomaly begins at position 52, is at a maximum at position 39 and disappears at position 29. It is important to note that, in this case, the air gap deviation according to FIG. 3 would have remained acceptable, since at no time was the minimum critical air gap value reached. Upon visual inspection of the machine following acquisition of this measurement set, a loose rim section was discovered.

Analysis over time of the changes inside the matrix, and the graphical rendering of the stator and rotor roundness and concentricity may indicate that the shape of the rotor or of the stator is abnormal or changing and that risks of operation malfunction are increasing. However, such an analysis is not instantaneous, requires a large memory of registered values per turn and requires expert interpretation before leading to a decision to stop the machine to assess the possible danger due to rotor or stator shape change. Alarms based on stator roundness, stator concentricity, rotor roundness and rotor concentricity deviations would not be appropriate in real time and it may then be too late to avoid destruction of the machine.

Accordingly, a problem of detection and notification remains since the occurrence of rotor or stator shape changes should be brought to the attention of machine operators in real time and sufficiently in advance so as to allow a subsequent analysis of the cause of the shape change before any substantial damage is incurred.

### SUMMARY

According to one broad aspect, there is provided a warning system for a large electric rotating machine with salient pole rotor informing in real time operators of the machine about a change of shape of the rotor and/or the stator of the machine, the system comprising: air gap measuring sensors affixed around the stator at known and predefined intervals, and real time measurements by the sensors of minimum air gap thickness for each rotor pole passing in front of each the sensor, a one per revolution reference means to identify each pole number and its position angle on the rotor, and reference values of minimum air gap thickness being stored as one reference value for each pole, and at each sensor position, when the machine is deemed to operate under normal conditions, and one or several warning signals informing of one or several changes of the shape of the rotor and/or of the stator, the signal or signals being generated whenever at least one real time air gap measurement made by a sensor for a given rotor pole differs positively or negatively from the reference value for the pole and for the sensor by a predefined minimum percentage.

In one embodiment, the reference minimum air gap thickness values are obtained by measuring the minimum air gap thickness for each rotor pole passing in front of each sensor when the machine is deemed to operate under normal conditions.

In one embodiment, the minimum air gap thickness reference values are obtained by measuring the minimum air gap thickness for each rotor pole passing in front of each sensor when the machine is operating at predetermined conditions, and whereby the reference values are validated by determining and analyzing the shapes of the rotor and stator deduced from the air gap data collected during the time the machine is operating under the predetermined conditions.

In one embodiment, a predefined minimum percentage is chosen, by which a real time measurement made by a sensor for a given rotor pole may not differ positively or negatively from its reference value without a warning signal being emitted.

According to another broad aspect, there is provided a monitoring system for an electric rotating machine with salient pole rotor, comprising: at least one air gap measuring sensor affixed on the stator at a sensor position, the sensor producing real time measurements of minimum air gap thickness for each passing rotor pole and associating the real time measurements to a unique identifier for each rotor pole; a memory for storing reference values of minimum air gap thickness for each rotor pole and each sensor position, the reference values being representative of the minimum air gap thickness when the machine is deemed to operate under normal conditions; a comparator for comparing corresponding ones of the real time measurements and the references values and identifying a positive or negative variation in the minimum air gap thickness greater than a predetermined minimum percentage; and a warning signal generator for emitting at least one warning signal upon the identification, wherein the warning signal informs of at least one change in the shape of the rotor and/or of the stator.

In one embodiment, the at least one air gap measuring sensor is a plurality of air gap measuring sensors disposed around the stator at known and predetermined intervals.

In one embodiment, the reference minimum air gap thickness values are obtained by measuring the minimum air gap thickness for each rotor pole passing in front of each sensor when the machine is deemed to operate under normal conditions.

In one embodiment, the minimum air gap thickness reference values are obtained by measuring the minimum air gap thickness for each rotor pole passing in front of each sensor when the machine is operating under predetermined conditions, and wherein the reference values are validated by determining and analyzing the shapes of the rotor and stator deduced from the air gap data collected during the time the machine is operating under the predetermined conditions.

In one embodiment, the warning signal generator sends the warning signal to a remote receiver.

According to another broad aspect of the present invention, there is provided a monitoring system for an electric rotating machine with salient pole rotor, comprising: at least one air gap measuring sensor affixed on the stator, the sensor producing real time measurements of minimum air gap thickness for each passing rotor pole; a memory for storing reference values of minimum air gap thickness for each rotor pole and each sensor position, the reference values corresponding to normal conditions; a comparator for comparing corresponding ones of the real time measurements and the references values and identifying a positive or negative variation in the minimum air gap thickness greater than a predetermined minimum percentage; and a warning signal generator for emitting at least one warning signal upon the identification.

According to another broad aspect of the present invention, there is provided a monitoring system for a rotating machine including a stator and a rotor. The method comprises at least one gap measuring sensor affixed on the stator at a sensor position, the sensor producing real time measurements of gap thickness for each passing rotor reference point and associating the real time measurements to a unique identifier for each rotor reference point; a memory for storing reference values of gap thickness for each rotor reference point and each sensor position; a comparator for comparing corresponding ones of the real time measurements and the references values and identifying a positive or negative variation in the gap thickness greater than a predetermined minimum percentage; and a warning signal generator for emitting at least one warning signal upon the identifying, wherein the warning signal is a notification of at least one change in the shape of the rotor and/or of the stator.

In one embodiment, the rotating machine is an electric rotating machine with a salient pole rotor and the reference point is a pole.

In one embodiment, the at least one air gap measuring sensor is a plurality of air gap measuring sensors disposed around the stator at known positions.

In one embodiment, the reference values of gap thickness are representative of the air gap thickness for each rotor reference point passing in front of each sensor when the machine is deemed to operate under one of satisfactory conditions and predetermined conditions.

In one embodiment, the system further comprises a reference value processor for validating the reference values of gap thickness by determining and analyzing the shapes of the rotor and stator.

In one embodiment, the warning signal generator sends the warning signal to a remote receiver.

### BRIEF DESCRIPTION OF THE DRAWINGS

Having thus generally described the nature of the invention, reference will now be made to the accompanying drawings, showing by way of illustration example embodiments thereof and in which:

FIG. 1 shows the rotor and stator profiles obtained by four equally spaced sensors that measure the air gap thickness facing each of 64 rotor poles;

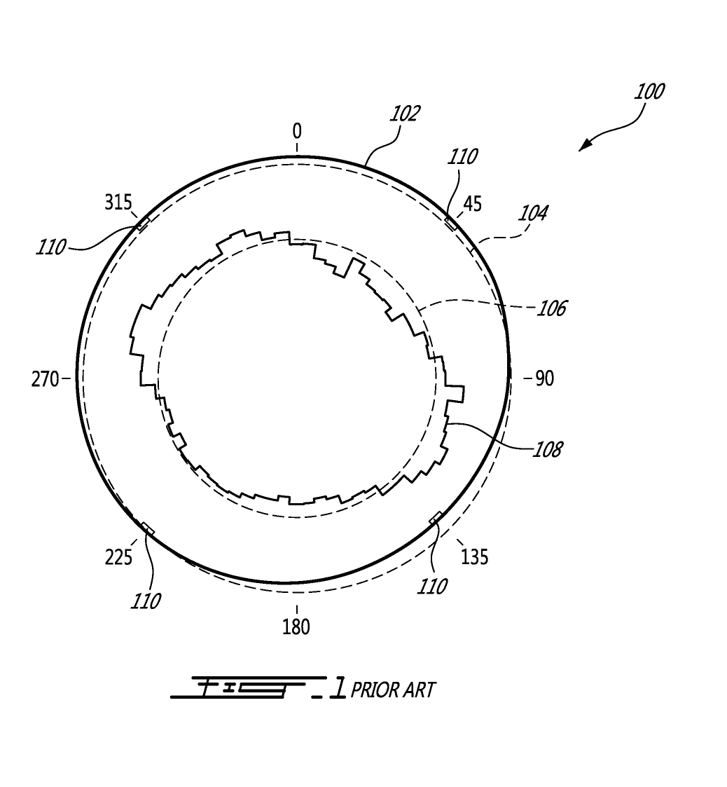

FIG. 2 shows the air gap thickness (vertical scale) as measured by each sensor for each passing pole (horizontal scale) over one machine turn;

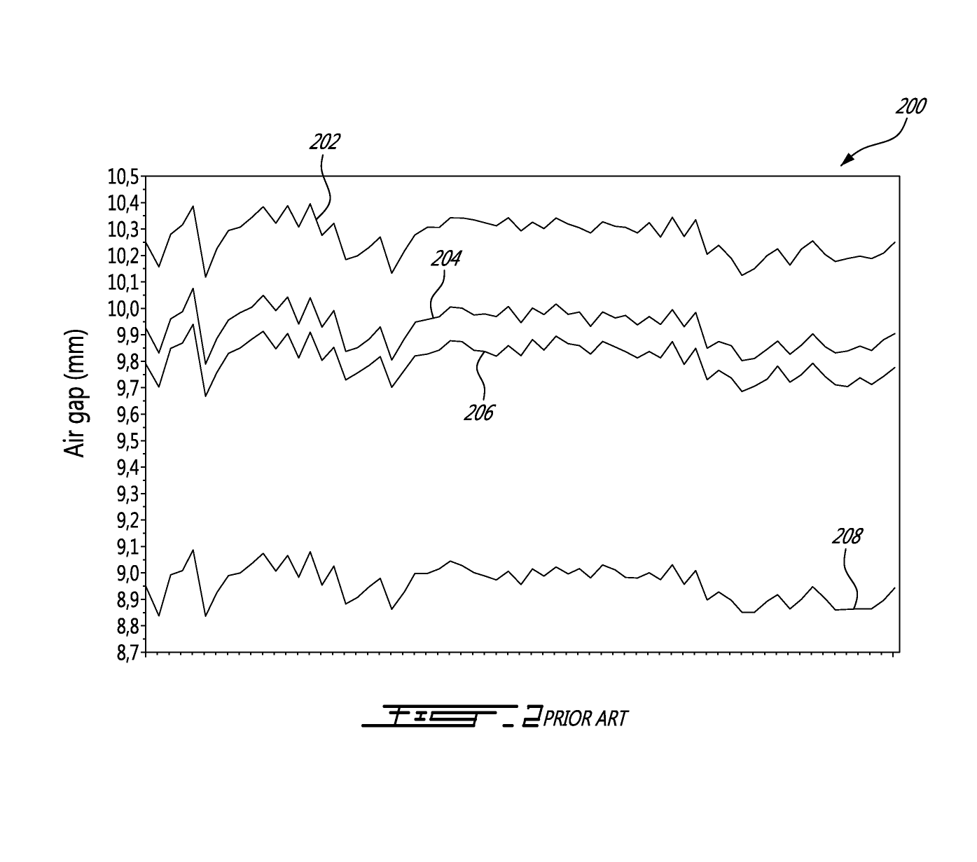

FIG. 3 is a table showing example alarm levels for mechanical tolerances of the machine;

FIG. 4 shows an example case of rotor shape change due to a loose rim section detected by comparison during a time period of 9 days;

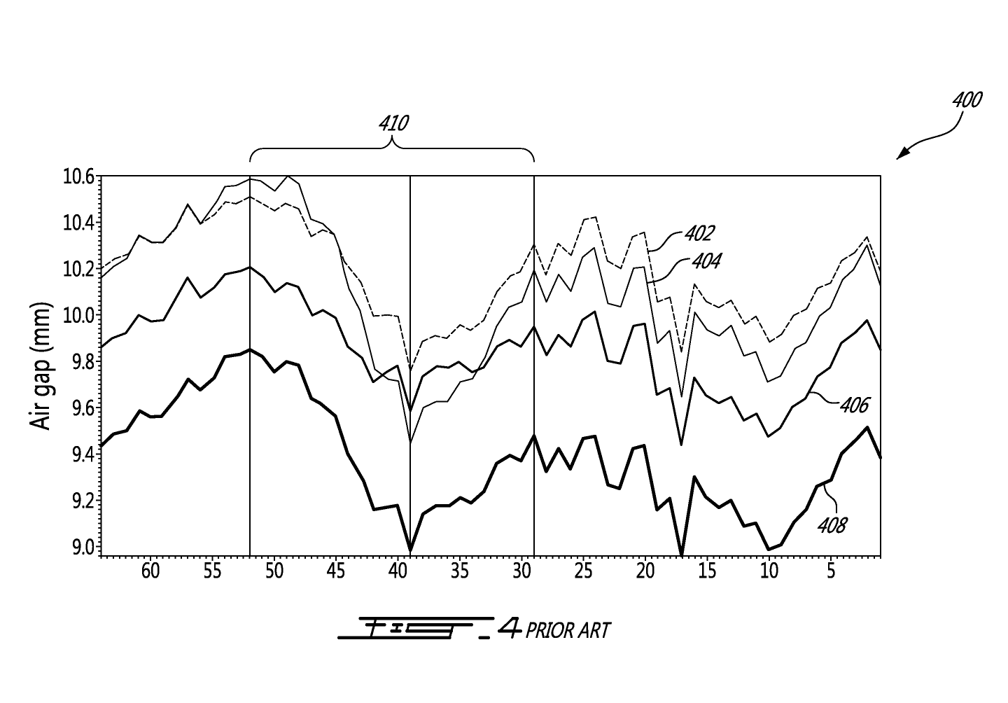

FIG. 5 is a flow chart of main steps of an example detection method for the real time monitoring of rotor or stator shape change for rotating machines; and

FIG. 6 is a block diagram of main components of an example detection system for the real time monitoring of rotor or stator shape change for rotating machines.

It will be noted that throughout the appended drawings, like features are identified by like reference numerals.

### DETAILED DESCRIPTION

The present system and method allow for the continuous protection of a salient pole rotating electric machine by detecting a rotor or stator shape change in real time in addition to the usual protection against the critical reduction of the air gap thickness.

Any change in the shape of the rotor or of the stator will result in at least one change in the air gap value measured for a given rotor pole by a given sensor.

Consequently, to ensure an immediate, continuous and exhaustive detection of a deformation of the rotor or stator, a continuous real time comparison of the air gap thickness facing each sensor for each pole is sufficient. There is no need to proceed with a complete and periodic analysis of the air gap measurement data to recalculate the shapes of the rotor and stator at any given time and assess their shape changes over time.

Practically, each air gap measurement for each pole by each sensor will be compared to a reference value predetermined for that same pole by that same sensor and stored in a memory, and an alarm will be raised as soon as an actual measurement differs from the reference value by a predetermined percentage.

The reference data stored in memory should correspond to air gap values measured when the machine is operating under satisfactory conditions, for instance at nominal speed and under no load with magnetic field activated and during a predetermined testing time period, or at nominal speed and under full load and during a predetermined testing time period once stator temperature has stabilized. Such reference data, before being permanently stored as such, should be validated by an extensive analysis indicating that the rotor and stator reference shapes are satisfactory and within specifications. This extensive analysis can be performed by a reference value processor programmed with computer-readable instructions. In one embodiment, the predetermined conditions are deemed acceptable or satisfactory and memorized as reference data only when predetermined conditions under no load are identical to the predetermined conditions obtained under full load.

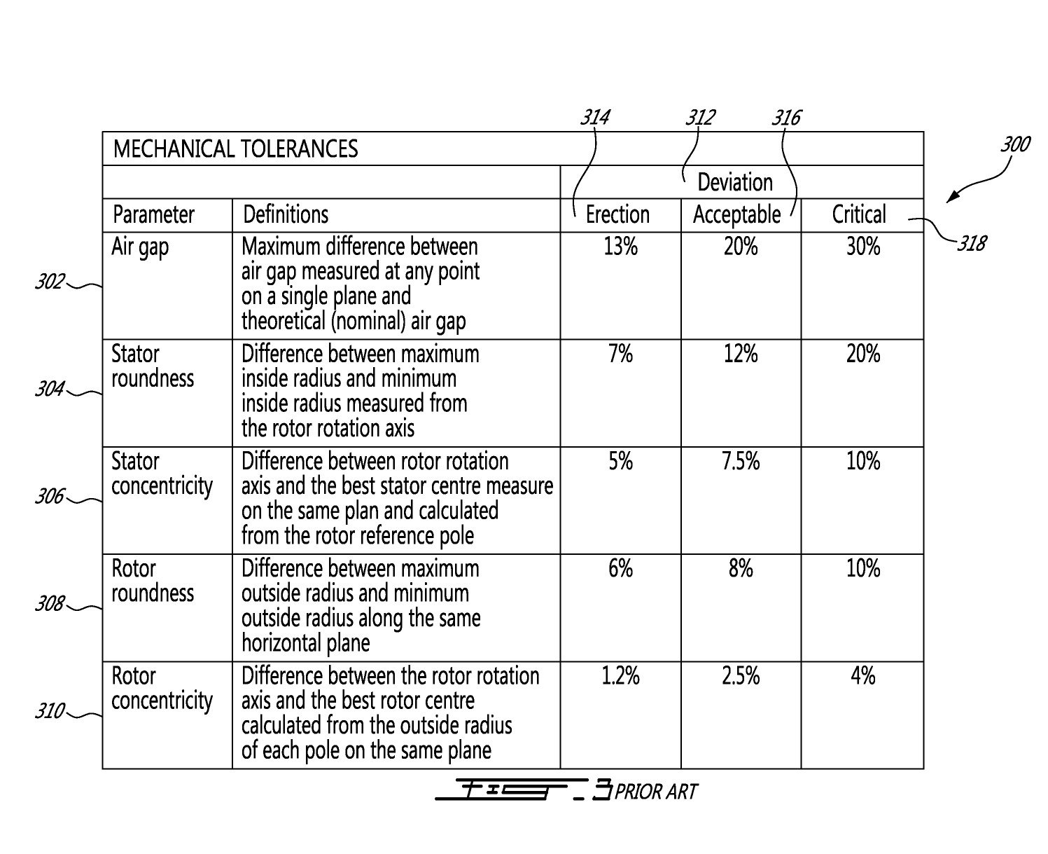

For instance, for a 60 pole machine with 8 air gap sensors, 480 reference values will be predetermined and memorized, 480 real time air gap measurements will be made at each turn, each one will be compared to its reference value, and an alarm will be raised if one of these measurements differs from its reference value by a predetermined minimum percentage, such as ±5%, ±10% or ±20% for example. This can be referred to as the predetermined alarm percentage. The machine may be stopped for investigation and repair if one measurement differs from its reference value by another predetermined percentage, a predetermined stop percentage, such as ±10%, ±20% or ±30%, for example. The percentages may be selected according to acceptable tolerances approved by the industry, for example based on the figures provided in FIG. 3. The percentages may be selected to be more strict than approved tolerances. For example, the predetermined minimum percentage may be chosen between 1% and 20%.

This creates a real time low cost detection tool since a limited number of memorized reference measurements are necessary and no repetitive, continuous or time-consuming sophisticated analysis is required.

In the field of hydroelectric plants, there is also a need with hydraulic turbines, such as Francis or Kaplan turbines, to monitor in real time the shapes of the lateral sides of the rotor and the interior wall lining shape of the stator to ensure that such turbines keep running efficiently, giving sufficient lead time to their operators to determine the probable cause of a detected rotor or stator shape change and the acceptability of such cause. In that case, the measurement of the minimum clearance between the rotating part and the wall lining will be obtained by choosing, instead of rotor poles, one or several reference points (or virtual poles) on the rotor by using a “synchro probe” (or “key phaser”) that provides for the sensor(s) affixed on the wall lining one pulse per turn at one or several fixed positions on the rotating part.

It should be noted that the above description of a method for real time detection of a rotor or stator shape change that applies to large electrical machines with salient pole rotors such as hydroelectric generators, also applies just as well to the large salient pole electric motors used in the mining industry to drive the rotation of the drums of gearless SAG mills.

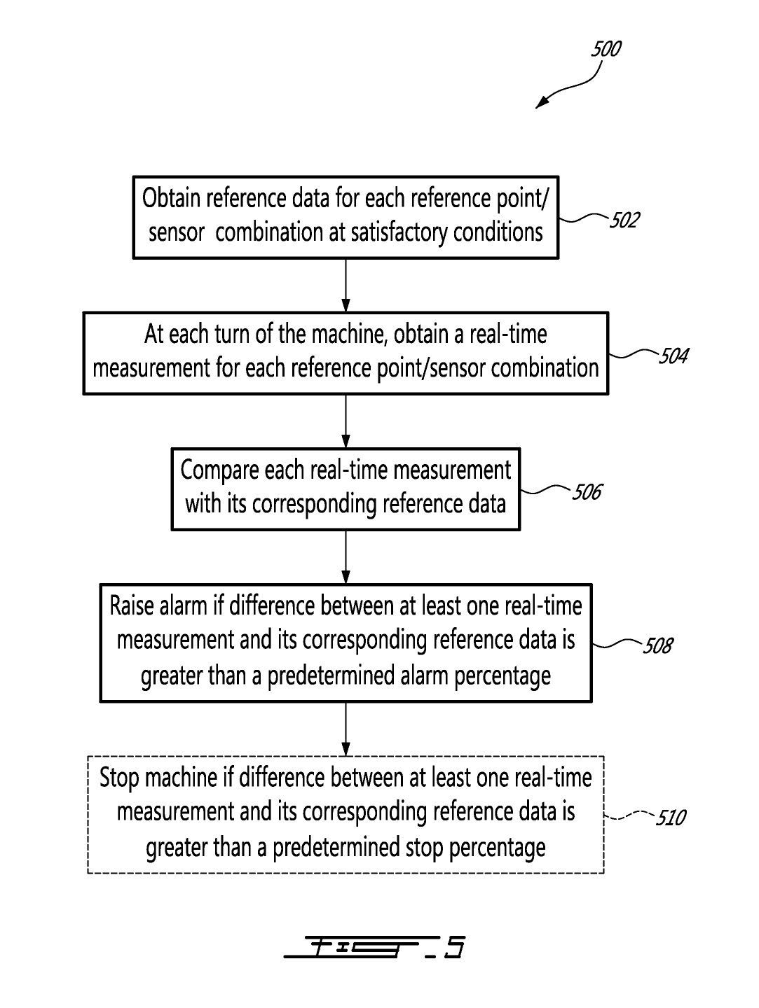

In short, the method 500 can therefore be summarized as follows with reference to FIG. 5. Obtain reference data for a reference point/sensor combination at satisfactory conditions 502. The reference point can be a pole or a user-selected reference point. At each turn of the machine, obtain a real-time measurement for each reference point/sensor combination 504. The real-time measurement can be a real-time air gap measurement or other relevant distance or thickness measurement. Compare each real-time measurement with its corresponding reference data 506. Raise alarm if difference between at least one real-time measurement and its corresponding reference data is greater than a predetermined alarm percentage 508. In some embodiments, the alarm may only be raised if a predetermined number of comparisons are greater than the predetermined alarm percentage. If appropriate, stop machine if difference between at least one real-time measurement and its corresponding reference data is greater than a predetermined stop percentage 510.

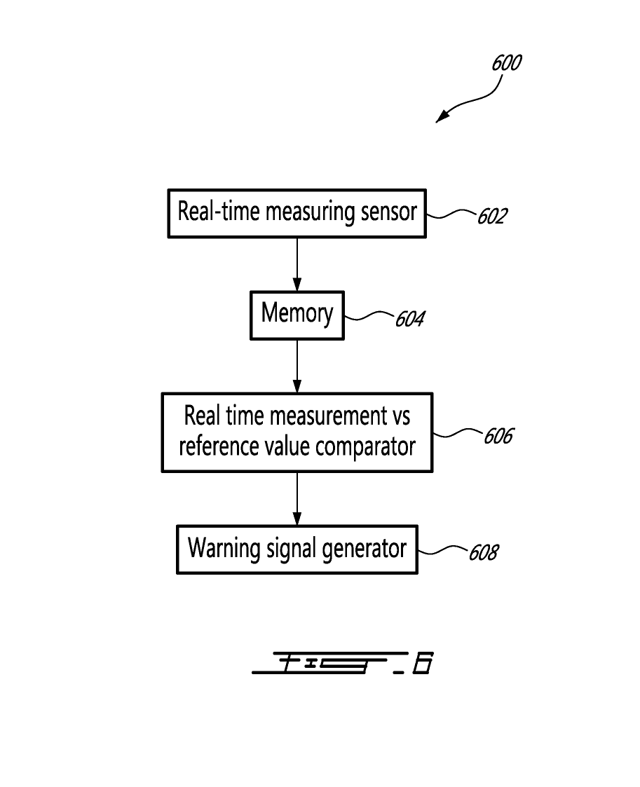

The monitoring system 600 for an electric rotating machine can be summarized as follows with reference to FIG. 6. At least one measuring sensor 602 acquires real time measurement data about the air gap. A memory 604 stores the previously obtained reference data and the current real time measurement date. A comparator 606 is used to compare the real time measurements with the stored reference values. A warning signal generator 608 is used to generate an alarm and can send this warning signal to a remote receiver. An optional reference value processor may also be provided and it is used for validating the reference values of gap thickness by determining and analyzing the shapes of the rotor and stator.

The embodiments described above are intended to be exemplary only. The scope of the invention is therefore intended to be limited solely by the appended claims.

1. A monitoring system for a rotating machine including a stator and a rotor, comprising:
at least one gap measuring sensor affixed on the stator at a sensor position, said sensor producing real time measurements of gap thickness for each passing rotor reference point and associating said real time measurements to a unique identifier for each rotor reference point;
a memory for storing reference values of gap thickness for each rotor reference point and each sensor position;
a comparator for comparing corresponding ones of said real time measurements and said references values and identifying a positive or negative variation in said gap thickness greater than a predetermined minimum percentage; and
a warning signal generator for emitting at least one warning signal upon said identifying, wherein said warning signal is a notification of at least one change in the shape of the rotor and/or of the stator.

2. The monitoring system as claimed in claim 1, wherein said rotating machine is an electric rotating machine with a salient pole rotor and wherein said reference point is a pole.

3. The monitoring system as claimed in claim 1, wherein said at least one air gap measuring sensor is a plurality of air gap measuring sensors disposed around the stator at known positions.

4. The monitoring system of claim 1 wherein the reference values of gap thickness are representative of the air gap thickness for each rotor reference point passing in front of each sensor when the machine is deemed to operate under one of satisfactory conditions and predetermined conditions.

5. The monitoring system of claim 1 further comprising a reference value processor for validating the reference values of gap thickness by determining and analyzing the shapes of the rotor and stator.

6. The monitoring system of claim 1, wherein said warning signal generator sends said warning signal to a remote receiver.
